(19) United States
(12) Patent Application Publication
(10) Pub. No.: US 2012/0061729 A1
(43) Pub. Date: Mar. 15, 2012

(54) NITRIDE SEMICONDUCTOR DEVICE AND METHOD FOR FABRICATING THE SAME

(75) Inventors: Daisuke SHIBATA, Kyoto (JP); Manabu YANAGIHARA, Osaka (JP); Yasuhiro UEMOTO, Toyama (JP)

(73) Assignee: Panasonic Corporation, Osaka (JP)

(21) Appl. No.: 13/295,762

(22) Filed: Nov. 14, 2011

Related U.S. Application Data
(63) Continuation of application No. PCT/JP2010/002824, filed on Apr. 19, 2010.

(30) Foreign Application Priority Data
Jul. 22, 2009 (JP) 2009-170847

(51) Int. Cl. H01L 29/778; H01L 21/20

(52) U.S. Cl. 257/194; 438/478; 257/E29.246; 257/E21.09

(57) ABSTRACT

A nitride semiconductor device includes a semiconductor layer stack including a first nitride semiconductor layer and a second nitride semiconductor layer stacked in this order on a substrate. A p-type third nitride semiconductor layer is selectively formed on the semiconductor layer stack, and a gate electrode is formed on the third nitride semiconductor layer. A first ohmic electrode and a second ohmic electrode are formed on regions of the semiconductor layer stack located at both sides of the third nitride semiconductor layer, respectively. A first gate electrode forms a Schottky contact with the third nitride semiconductor layer.

### CROSS-REFERENCE TO RELATED APPLICATION

This is a continuation of PCT International Application PCT/JP2010/002824 filed on Apr. 19, 2010, which claims priority to Japanese Patent Application No. 2009-170847 filed on Jul. 22, 2009. The disclosures of these applications including the specifications, the drawings, and the claims are hereby incorporated by reference in their entirety.

### BACKGROUND

The present disclosure relates to a nitride semiconductor device and a method for fabricating the nitride semiconductor device, and more particularly relates to a nitride semiconductor device which can be used as a power transistor, etc. and a method for fabricating the nitride semiconductor device.

Nitride semiconductors represented by gallium nitride (GaN) are wide gap semiconductors. For example, GaN and aluminum nitride (AlN) have band gaps as large as of 3.4 eV and 6.2 eV, respectively, at room temperature. The nitride semiconductors have high breakdown field strength, and high saturated drift velocity of electrons as compared with compound semiconductors such as gallium arsenide (GaAs) etc., or silicon (Si) semiconductors, etc. In a heterostructure of an aluminum gallium nitride (AlGaN) layer and a GaN layer on plane (0001), charges are generated at a heterointerface due to spontaneous polarization and piezoelectric polarization. The charges generated at the heterointerface between AlGaN and GaN have a sheet carrier concentration of 1×10¹³ cm⁻² or higher even when AlGaN and GaN are undoped. A hetero junction field effect transistor (HFET) having high current density, and low on-resistance can be provided by using two-dimensional electron gas (2 DEG) generated at the heterointerface (see, for example, 1W. Saito et al., IEEE Transactions on Electron Devices, 2003, vol. 50, No. 12, p. 2528).

However, in a heterojunction in nitride semiconductor, even when the nitride semiconductor is not doped, high concentration carriers are generated at the interface due to spontaneous polarization and piezoelectric polarization. Therefore, a FET employing a nitride semiconductor is likely to be of the depletion mode type (normally-on type), but not of the enhancement mode type (normally-off type). Because most of the devices currently used in the field of power electronics are of the normally-off type, there is a strong demand for normally-off GaN-based nitride semiconductor devices as well.

As a method for realizing a normally-off GaN-based nitride semiconductor device, it has been known to provide a p-type nitride semiconductor layer below a gate electrode (see, for example, Japanese Patent Publication No. 2006-339561). With the p-type nitride semiconductor layer provided below the gate electrode, a pn junction is formed between 2 DEG generated at an interface between an AlGaN layer and a GaN layer, and a p-type nitride semiconductor layer. Thus, even when a bias voltage is not applied to the gate electrode, a depletion layer extends from the p-type nitride semiconductor layer to 2 DEG, so that the normally-off GaN-based nitride semiconductor device can be realized.

### SUMMARY

However, it has been found that, in a conventional GaN-based nitride semiconductor device in which a p-type nitride semiconductor layer is provided, when a forward bias is applied to a gate electrode, a gate leakage current flows. The gate leakage current causes a power dissipation at a gate, which causes the generation of heat. In power devices used for power supply sources, etc., the chip size has to be large, and the power dissipation in the gate portion increases as the chip size increases. Furthermore, another problem arises in which, when the gate leakage current increases, the driving capability of a gate driving circuit has to be increased as well. As described above, in a GaN-based nitride semiconductor device, it is very important to reduce the gate leakage current.

It is an object of the present disclosure to solve the above-described problems and realize a nitride semiconductor device in which a gate leakage current generated when a forward bias is applied to a gate electrode is reduced.

To achieve the above-described object, a nitride semiconductor device according to the present disclosure includes a gate electrode which forms a Schottky contact with a p-type nitride semiconductor layer.

Specifically, an example nitride semiconductor device includes a substrate, a semiconductor layer stack including a first nitride semiconductor layer and a second nitride semiconductor layer stacked in this order on the substrate, the second nitride semiconductor layer having a wider bandgap than that of the first nitride semiconductor layer, a p-type third nitride semiconductor layer selectively formed on the semiconductor layer stack, a first gate electrode formed on the third nitride semiconductor layer, and a first ohmic electrode and a second ohmic electrode formed on regions of the semiconductor layer stack located at both sides of the third nitride semiconductor layer, respectively, and the first gate electrode forms a Schottky contact with the third nitride semiconductor layer.

In the example nitride semiconductor device, a Schottky barrier is generated between the first gate electrode and the third nitride semiconductor layer to interfere with a current flow from the first gate electrode side to the third nitride semiconductor layer side. Therefore, a gate leakage current can be greatly reduced, as compared to a configuration in which the first gate electrode forms an ohmic contact with the third nitride semiconductor layer. As a result, a nitride semiconductor device in which a gate leakage current generated when a forward bias is applied to a gate electrode is reduced can be realized.

In the example nitride semiconductor device, the first gate electrode, the first ohmic electrode, and the second ohmic electrode may be made of the same material. Thus, the first gate electrode, the first ohmic electrode, and the second ohmic electrode can be formed by a single process step, so that a method for fabricating the nitride semiconductor device can be simplified.

In the example nitride semiconductor device, the first gate electrode, the first ohmic electrode, and the second ohmic electrode may be each made of one of titanium, aluminum, tungsten, molybdenum, chromium, zirconium, indium, and tungsten silicide, or a stack including two or more of titanium, aluminum, tungsten, molybdenum, chromium, zirconium, indium, and tungsten silicide.

In the example nitride semiconductor device, a width of the first gate electrode in a gate length direction and a width of the third nitride semiconductor layer in the gate length direction may be equal to each other.

In the example nitride semiconductor device, the first gate electrode and the third nitride semiconductor layer may be etchable by the same etching gas.

In the example nitride semiconductor device, a carrier concentration of the third nitride semiconductor layer may be 1×10¹⁸ cm⁻³ or higher and 1×10²¹ cm⁻³ or lower.

In the example nitride semiconductor device, the second nitride semiconductor layer may have a gate recess, and the third nitride semiconductor layer may be formed to fill the gate recess.

The example nitride semiconductor device may further include a p-type fourth nitride semiconductor layer which is formed on the semiconductor layer stack to be located between the first gate electrode and the second ohmic electrode, and a second gate electrode formed on the fourth nitride semiconductor layer, and the second gate electrode may form a Schottky contact with the fourth nitride semiconductor layer.

A first method for fabricating a nitride semiconductor device according to the present disclosure includes the steps of (a) forming, on a substrate, a semiconductor layer stack including a first nitride semiconductor layer and a second nitride semiconductor layer stacked in this order, the second nitride semiconductor layer having a wider bandgap than that of the first nitride semiconductor layer, (b) forming a p-type nitride semiconductor layer on the semiconductor layer stack, and then, selectively removing the p-type nitride semiconductor layer, thereby forming a third nitride semiconductor layer, and (c) forming a first ohmic electrode and a second ohmic electrode on regions of the semiconductor layer stack located at both sides of the third nitride semiconductor layer, respectively, and at the same time, forming a first gate electrode on the third nitride semiconductor layer.

According to the first method for fabricating a nitride semiconductor device, a material which forms a Schottky contact with the p-type nitride semiconductor layer can be caused to form an ohmic contact with a two-dimensional electron gas layer. Thus, the first ohmic electrode, the second ohmic electrode, and the first gate electrode can be made of the same material. Therefore, the first ohmic electrode, the second ohmic electrode, and the first gate electrode can be formed at the same time, so that fabrication process steps can be simplified.

In the first method for fabricating a nitride semiconductor device, in step (c), the first gate electrode, the first ohmic electrode, and the second ohmic electrode may be formed by forming a resist mask to expose regions where the first gate electrode, the first ohmic electrode, and the second ohmic electrode are to be formed, and then, performing deposition and liftoff of an electrode formation film.

In the first method for fabricating a nitride semiconductor device, the electrode formation film may be a film made of one of titanium, aluminum, tungsten, molybdenum, chromium, zirconium, indium, and tungsten silicide, or a stacked film including two or more of titanium, aluminum, tungsten, molybdenum, chromium, zirconium, indium, and tungsten silicide.

The first method for fabricating a nitride semiconductor device may further include, after the step (a) and before the step (b), the step (d) of forming a gate recess in the second nitride semiconductor layer, and in the step (b), the p-type nitride semiconductor layer may be formed to fill the gate recess.

In the first method for fabricating a nitride semiconductor device, in the step (b), a p-type fourth nitride semiconductor layer may be formed with a distance from the third nitride semiconductor layer, and in the step (c), a second gate electrode may be formed on the fourth nitride semiconductor layer. Thus, a nitride semiconductor device having a double gate structure can be formed in a simple manner.

A second method for fabricating a nitride semiconductor device includes the steps of (a) forming, on a substrate, a semiconductor layer stack including a first nitride semiconductor layer and a second nitride semiconductor layer stacked in this order, the second nitride semiconductor layer having a wider bandgap than that of the first nitride semiconductor layer, (b) forming a p-type nitride semiconductor layer and a gate electrode formation film in this order on the semiconductor layer stack on the substrate, (c) selectively removing the gate electrode formation film and the p-type nitride semiconductor layer in this order to form a third nitride semiconductor layer and a first gate electrode on the semiconductor layer stack so that the first gate electrode forms a Schottky contact with the third nitride semiconductor layer, and (d) forming a first ohmic electrode and a second ohmic electrode on regions of the semiconductor layer stack located at both sides of the third nitride semiconductor layer, respectively.

A material which forms a Schottky contact with the p-type nitride semiconductor layer can be easily dry etched. Thus, the third nitride semiconductor layer and the first gate electrode can be formed to be self-aligned, so that the size of the first gate electrode can be further reduced. Reduction in size of the first gate electrode advantageously results in reduction in on resistance and forward gate current due to reduction in gate length and gate area. Furthermore, a contact area of the first gate electrode and the third nitride semiconductor layer can be increased, thus resulting in reduction in interconnect resistance.

In the second method for fabricating a nitride semiconductor device, the gate electrode formation film and the p-type nitride semiconductor layer may be etchable by the same etching gas.

In the second method for fabricating a nitride semiconductor device, the gate electrode formation film may be a film made of one of titanium, aluminum, tungsten, molybdenum, and tungsten silicide, or a stacked film including two or more of titanium, aluminum, tungsten, molybdenum, and tungsten silicide.

The second method for fabricating a nitride semiconductor device may further include, after the step (a) and before the step (b), the step (e) of forming a gate recess in the second nitride semiconductor layer, and in the step (b), the p-type nitride semiconductor layer may be formed to fill the gate recess.

In the second method for fabricating a nitride semiconductor device, in the step (c), a p-type fourth nitride semiconductor layer and a second gate electrode may be formed with a distance from the third nitride semiconductor layer and the first gate electrode. Thus, a nitride semiconductor device having a double gate structure can be formed in a simple manner.

In the first and second methods for fabricating a nitride semiconductor device, a carrier concentration of the p-type nitride semiconductor layer may be 1×10¹⁸ cm⁻³ or higher and 1×10²¹ cm⁻³ or lower.

According to the present disclosure, a nitride semiconductor device in which a gate leakage current generated when a forward bias is applied to a gate electrode is reduced can be realized.

### BRIEF DESCRIPTION OF THE DRAWINGS

FIG. 1 is a cross-sectional view illustrating a nitride semiconductor device according to one embodiment.

FIG. 2 is a graph showing current-voltage characteristics between a gate and a source in a nitride semiconductor device according to one embodiment.

FIGS. 3A-3D are cross-sectional views illustrating respective steps for fabricating a nitride semiconductor device according one embodiment.

FIGS. 4A-4C are cross-sectional views illustrating respective steps for fabricating a nitride semiconductor device according to one embodiment.

FIGS. 5A-5C are cross-sectional views illustrating respective steps for fabricating a nitride semiconductor device according to a variation of one embodiment.

FIGS. 6A-6C are cross-sectional views illustrating respective steps for fabricating a nitride semiconductor device according to one embodiment.

FIG. 7 is a cross-sectional view illustrating a nitrides semiconductor device according to another variation of one embodiment.

FIGS. 8A and 8B are cross-sectional views illustrating respective steps for fabricating a nitride semiconductor device according to one embodiment.

FIG. 9 is a cross-sectional view of a nitride semiconductor device according to still another variation of one embodiment.

### DETAILED DESCRIPTION

In the present disclosure, AlGaN designates a ternary compound AlₓGa₁₋ₓN (where 0≦x≦1). Compounds are abbreviated as, for example, AlInN, GaInN, etc., which are symbols of elements constituting the crystal. For example, nitride semiconductor AlₓGa_{1-x-y}In_{y}N (where 0≦x≦1, 0≦y≦1, x+y≦1) is abbreviated as AlGaInN. The term “undoped” means that impurities are not intentionally introduced. The symbol “p⁺” indicates that high concentration p-type carriers are contained.

### One Embodiment

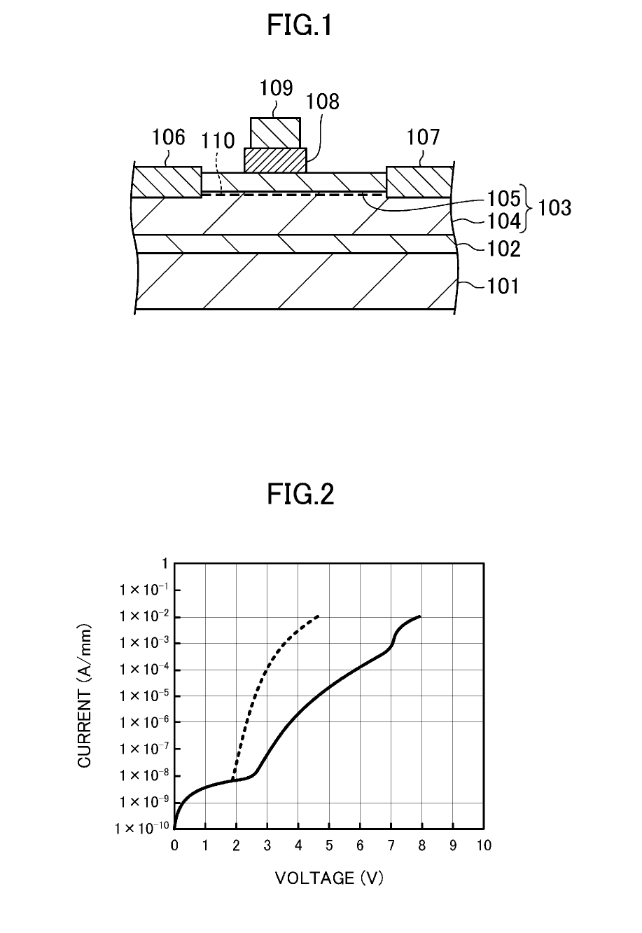

FIG. 1 illustrates a cross section of a nitride semiconductor device according to one embodiment. As shown in FIG. 1, a nitride semiconductor device according to this embodiment is an HFET employing a 2 DEG layer 110 as a channel, and includes a gate electrode 109 which forms a Schottky contact with a p-type third nitride semiconductor layer 108. Specifically, a semiconductor layer stack 103 is formed on a substrate 101 with a buffer layer 102 having a thickness of about 2 μm interposed therebetween. The substrate 101 may be made of any material as long as a nitride semiconductor can be crystal-grown thereon. For example, silicon (Si), sapphire, silicon carbide (SiC), and GaN, etc. can be used for the substrate 101. The semiconductor layer stack 103 may be made of any materials as long as the 2 DEG layer 110 can be formed. For example, the semiconductor layer stack 103 may be a stack of a first nitride semiconductor layer 104 made of an undoped GaN layer with a thickness of about 3 μm and a second nitride semiconductor layer 105 made of an undoped AlGaN layer with a thickness of about 25 nm. In this case, the 2 DEG layer 110 is formed in a part of the first nitride semiconductor layer 104 located near an interface with the second nitride semiconductor layer 105.

The third nitride semiconductor layer 108 made of p-type AlGaN with a thickness of about 200 nm is selectively formed on the semiconductor layer stack 103. On the third nitride semiconductor layer 108, the gate electrode 109 which forms a Schottky contact with the third nitride semiconductor layer 108 is formed. The third nitride semiconductor layer 108 may be any p-type semiconductor layer having a narrower bandgap than that of the second nitride semiconductor layer 105, and may be made of GaN, etc. Also, the third nitride semiconductor layer 108 may be made of a stack of a plurality of semiconductor layers. In this case, a layer in contact with the gate electrode 109 may be made of a P⁺—AlGaN layer.

A first ohmic electrode 106 serving as a source electrode and a second ohmic electrode 107 serving as a drain electrode are formed in regions of the semiconductor layer stack 103 located at both sides of the third nitride semiconductor layer 108, respectively. The first ohmic electrode 106 and the second ohmic electrode 107 form an ohmic contact with the 2 DEG layer 110. In this embodiment, recesses are formed in the semiconductor layer stack 103 to reach a deeper point than an interface between the first nitride semiconductor layer 104 and the second nitride semiconductor layer 105, and the first ohmic electrode 106 and the second ohmic electrode 107 are formed to fill the recesses.

In this embodiment, a greater distance is provided between the second ohmic electrode 107 and the third nitride semiconductor layer 108 than between the first ohmic electrode 106 and the third nitride semiconductor layer 108. Thus, a gate-drain breakdown voltage can be caused to be higher than a gate-source breakdown voltage. However, the distance between first ohmic electrode 106 and the third nitride semiconductor layer 108 may be equal to the distance between the second ohmic electrode 107 and the third nitride semiconductor layer 108.

Gate leakage characteristics of the nitride semiconductor device of this embodiment will be described below. FIG. 2 shows a comparison of gate leakage characteristics between the nitride semiconductor device of this embodiment and a conventional nitride semiconductor device. In FIG. 2, the horizontal axis indicates a gate-source voltage, and the vertical axis indicates a gate-source current. The broken line indicates gate leakage characteristics of the conventional nitride semiconductor device in which the gate electrode forms an ohmic contact with the p-type nitride semiconductor layer. The solid line indicates gate leakage characteristics of the nitride semiconductor device of this embodiment.

In the conventional nitride semiconductor device, the gate-source current drastically increases at a point where the gate-source voltage is around 2 V. Since a pn junction is formed by the p-type nitride semiconductor layer and the 2 DEG layer, a pn junction diode is formed between the gate and the source. When the gate electrode forms an ohmic contact with the p-type nitride semiconductor layer, no barrier exists. Therefore, when a forward bias voltage applied to the gate electrode exceeds a forward rising voltage of the pn junction diode, a large gate leakage current flows. For example, when the gate width is 100 mm and a driving voltage is 4 V, a gate leakage current is about 100 mA, resulting in a power dissipation of about 0.4 W at the gate.

On the other hand, in the nitride semiconductor device of this embodiment in which the gate electrode 109 forms a Schottky contact with the third nitride semiconductor layer 108 which is a p-type nitride semiconductor layer, as indicated by the solid line in FIG. 2, the increase in gate-source current is moderate, and the generation of the gate leakage current is reduced. For example, in FIG. 2, the gate leakage current when the gate-source voltage is 4 V is about one thousandth of the gate leakage current when the gate electrode 109 forms an ohmic contact with the third nitride semiconductor layer 108. Therefore, the power dissipation at the gate can be reduced to about one thousandth of the power dissipation at the gate when the gate electrode 109 forms an ohmic contact. This is because a Schottky barrier is generated between the gate electrode 109 and the third nitride semiconductor layer 108 to interfere with a current flow from the gate electrode 109 to the third nitride semiconductor layer 108.

When the gate electrode 109 and the third nitride semiconductor layer 108 form a Schottky contact, the gate resistance increases. The increase in gate resistance causes reduction in switching speed. However, in a power transistor used for a power supply source, etc., the switching speed is several hundred KHz to several MHz, and the increase in gate resistance due to the Schottky contact of the gate electrode 109 and the third nitride semiconductor layer 108 hardly affects the switching speed.

The gate electrode 109 may be made of any material as long as it forms a Schottky contact with the p-type nitride semiconductor layer. For example, the gate electrode 109 may be made of one of titanium (Ti), aluminum (Al), tungsten (W), molybdenum (Mo), chromium (Cr), zirconium (Zr), indium (In), and tungsten silicide (WSi), etc. The gate electrode 109 may be also made of a stack including these materials. For example, Ti and Al may be stacked in this order from the third nitride semiconductor layer 108 side. Also, the gate electrode 109 can be made of a stack of these materials and other materials. A material which forms a Schottky contact with the p-type nitride semiconductor layer is a material which normally forms an ohmic contact with the 2 DEG layer. Therefore, the gate electrode 109, the first ohmic electrode 106, and the second ohmic electrode 107 may be made of the same material.

The carrier concentration of the third nitride semiconductor layer 108 may be set so that the number of carriers per sheet in the third nitride semiconductor layer 108 is equal to or higher than the number of electrons in the 2 DEG layer 110. Specifically, the carrier concentration of the third nitride semiconductor layer 108 is preferably about 1×10¹⁸ cm⁻³ or higher, and more preferably about 1×10¹⁹ cm⁻³ or higher. For example, when the first nitride semiconductor layer 104 is undoped GaN and the second nitride semiconductor layer 105 is Al_{0.25}Ga_{0.75}N with a thickness of about 25 nm, the sheet charier concentration of the 2 DEG layer 110 is about 1×10¹³ cm⁻². In this case, when the thickness of the third nitride semiconductor layer 108 made of AlGaN is about 200 nm and the carrier concentration is about 1×10¹⁸ cm⁻³ or higher, 2 DEG can be canceled, and normally-off operation can be realized. The carrier concentration of the third nitride semiconductor layer 108 may be adjusted according to the thickness of the third nitride semiconductor layer 108, the thickness of the second nitride semiconductor layer 105, the Al composition of the second nitride semiconductor layer 105, and the necessary threshold voltage, etc. When normally-off operation is not necessary, the carrier concentration may be further reduced. However, the carrier concentration is too low, it is difficult to put a transistor into an on state. Since the leakage current can be reduced when the carrier concentration of the third nitride semiconductor layer is low, the carrier concentration is preferably about 1×10²¹ cm⁻³ or lower, and is more preferably about 1×10²⁰ cm⁻³ or lower. As a p-type impurity, magnesium (Mg) etc. may be used.

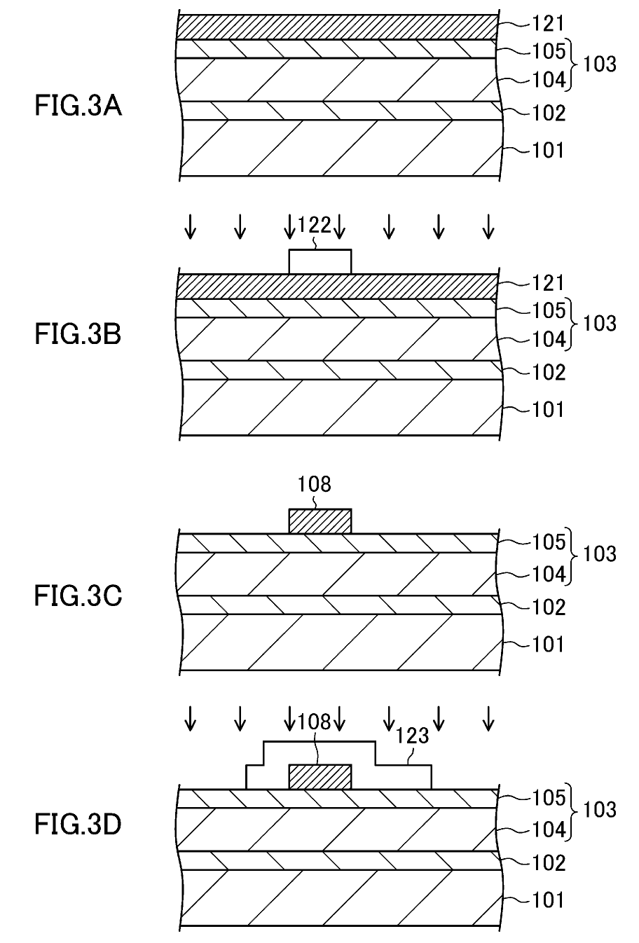

A method for fabricating a nitride semiconductor device according to this embodiment will be described below with reference to the accompanying drawings. First, as shown in FIG. 3A, a buffer layer 102, a first nitride semiconductor layer 104 made of undoped GaN, a second nitride semiconductor layer 105 made of undoped AlGaN, and a p-type AlGaN layer 121 are grown in this order on a substrate 101 using metal-organic chemical vapor deposition (MOCVD), etc. Instead of MOCVD, some other method may be used to grow the nitride semiconductor layers.

Next, as shown in FIG. 3B, an etching mask 122 is selectively formed. Subsequently, the p-type AlGaN layer 121 is selectively etched to form a third nitride semiconductor layer 108 as shown in FIG. 3C.

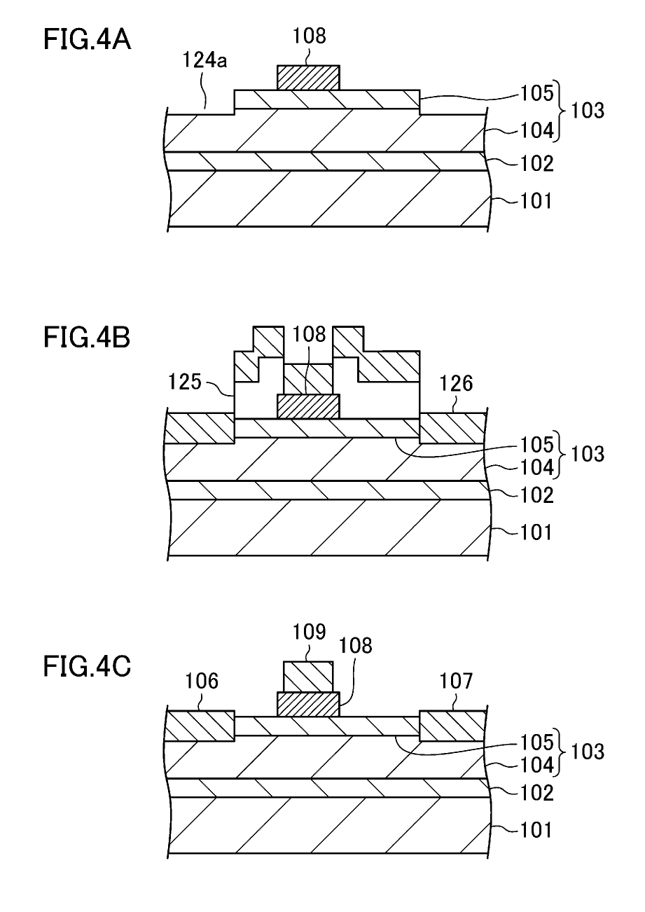

Next, as shown in FIG. 3D, an etching mask 123 is formed to have openings corresponding to regions where a first ohmic electrode 106 and a second ohmic electrode 107 are to be formed. Subsequently, parts of the second nitride semiconductor layer 105 and the first nitride semiconductor layer 104 are etched to form recesses 124a at both sides of the third nitride semiconductor layer 108, respectively, as shown in FIG. 4A.

Next, as shown in FIG. 4B, a resist pattern 125 to expose an upper surface of the third nitride semiconductor layer 108 and the recesses 124a is formed by lithography, etc. Thereafter, a Ti film and an Al film are stacked in this order to form an electrode formation film 126. Next, as shown in FIG. 4C, the electrode formation film 126 is lifted off to form a first ohmic electrode 106 as a source electrode, a second ohmic electrode 107 as a drain electrode, and a gate electrode 109.

According to the method for fabricating a nitride semiconductor device according to this embodiment, the first ohmic electrode 106, the second ohmic electrode 107, and the gate electrode 109 are formed at the same time. Thus, the number of process steps can be reduced, the throughput can be improved, and the cost can be reduced. However, the first ohmic electrode 106, the second ohmic electrode 107, and the gate electrode 109 do not have to be made of the same material, and in such a case, the first ohmic electrode 106, the second ohmic electrode 107, and the gate electrode 109 may be formed by separate process steps.

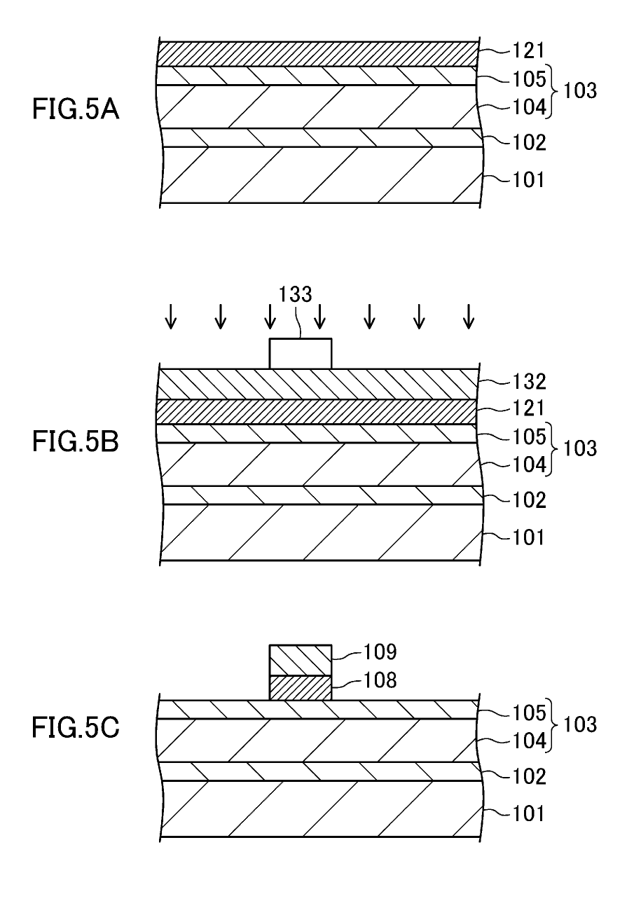

The nitride semiconductor device of this embodiment may be formed also in the following manner. First, as shown in FIG. 5A, a buffer layer 102, a first nitride semiconductor layer 104 made of undoped GaN, a second nitride semiconductor layer 105 made of undoped AlGaN, and a p-type AlGaN layer 121 are grown in this order on a substrate 101 using MOCVD, etc.

Next, as shown in FIG. 5B, a gate electrode formation film 132 made of Ti and Al stacked in this order is formed on the p-type AlGaN layer 121, and thereafter, an etching mask 133 is selectively formed on the gate electrode formation film 132.

Next, the gate electrode formation film 132 and the p-type AlGaN layer 121 are etched. Thus, as shown in FIG. 5C, the gate electrode 109 and the third nitride semiconductor layer 108 are formed.

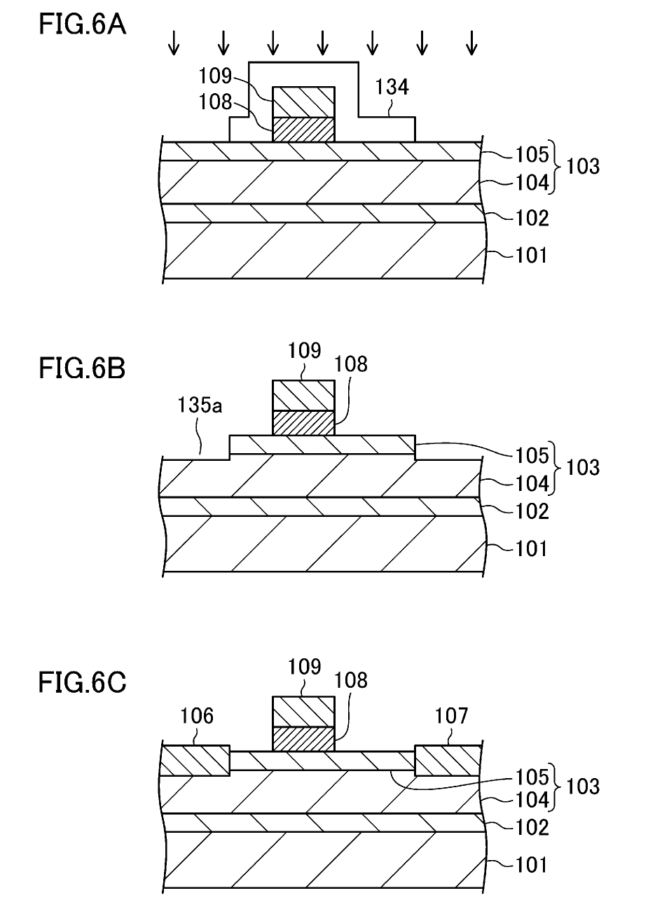

Next, as shown in FIG. 6A, an etching mask focus control section 134 is formed to have openings in regions in which a first ohmic electrode 106 and a second ohmic electrode 107 are to be formed. Subsequently, parts of the second nitride semiconductor layer 105 and the first nitride semiconductor layer 104 are etched to form recesses 135a at both sides of the third nitride semiconductor layer 108, respectively, as shown in FIG. 6C.

Next, as shown in FIG. 6C, a first ohmic electrode 106 and a second ohmic electrode 107 made of a stacked film of Ti and Al are formed to fill the recesses 135a.

When a gate electrode which forms an ohmic contact with a p-type nitride semiconductor is formed, palladium (Pd), platinum (Pt), or gold (Au), etc. having a large work function has to be used. It is difficult to dry etch these metal materials, and the gate electrode and the p-type nitride semiconductor layer under the gate electrode cannot be formed by the self-alignment process shown in FIG. 5B. However, in the semiconductor device of this embodiment, the gate electrode 109 is made of a stacked film of Ti and Al, etc. which forms a Schottky contact with the nitride semiconductor layer. Similar to nitride semiconductor, the stacked film of Ti and Al can be dry etched using chlorine based gas. Therefore, the gate electrode 109 and the third nitride semiconductor layer 108 can be formed by the self-alignment process.

When the gate electrode 109 is formed by a liftoff method after forming the third nitride semiconductor layer 108, mask misalignment has to be taken into consideration. Therefore, the width of the third nitride semiconductor layer 108 has to be made larger than the width of the gate electrode 109. However, since the third nitride semiconductor layer 108 and gate electrode 109 are formed using the self alignment process, the width of the third nitride semiconductor layer 108 in the gate length direction and the width of the gate electrode 109 in the gate length direction are equal to each other. Therefore, the sizes of the third nitride semiconductor layer 108 and the gate electrode 109 can be further reduced. Also, when the size of the gate electrode 109 is reduced, the on resistance and the forward gate current can be advantageously reduced due to reduction in gate length and gate area. Furthermore, a contact area of the gate electrode 109 and the third nitride semiconductor layer 108 can be increased by the self-alignment process, and thus, the interconnect resistance can be advantageously reduced.

When the gate electrode 109 and the third nitride semiconductor layer 108 are formed by the self-alignment process, the gate electrode 109 has to be made of a material which can be etched with the nitride semiconductor. Since a chlorine-based gas is normally used in etching of nitride semiconductor, a material which can be etched using a chlorine-based gas is selected. For example, Ti, Al, W, Mo, and Si, etc. can be etched by a chlorine-based gas. Therefore, when a film made of one of these materials, or a stacked film of these materials is used, the gate electrode 109 can be formed by the self-alignment process using a chlorine-based gas as an etchant. Cr, Zr, and In, etc. can be etched using a mixed gas of chlorine gas and argon gas. Thus, when a film made of one of these materials, or a stacked film of these materials is used, the gate electrode 109 can be formed by the self-alignment process using a mixed gas of chlorine gas and argon gas as an etchant. Similarly, a stacked film including one of Cr, Zr, and In, etc. and one of Ti, Al, W, Mo, and WSi, etc. can be used. Nitride semiconductor can be etched using a mixed gas of chlorine gas and silicon tetrachloride gas, etc. as an etchant. An electrode material which can be etched using such an etchant may be selected.

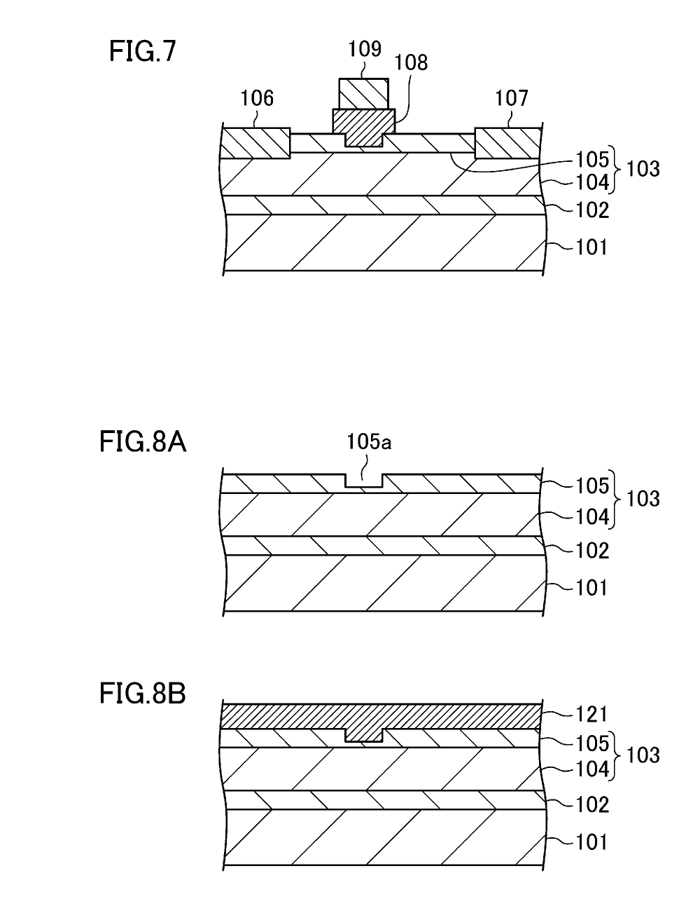

In this embodiment, the third nitride semiconductor layer is formed on the flat second nitride semiconductor layer. However, as shown in FIG. 7, a gate recess may be formed in the second nitride semiconductor layer 105, and then, the third nitride semiconductor layer 108 may be formed thereon. When a gate recess structure of FIG. 7 is provided, the second nitride semiconductor layer 105 can be formed to have an increased thickness without affecting characteristics of the gate electrode. When the second nitride semiconductor layer 105 has an increased thickness, a distance between the 2 DEG layer 110 and a surface of the semiconductor layer stack 103 can be increased, so that the generation of current collapse can be reduced.

When the gate recess structure is formed, as shown in FIG. 8A, after growing layers up to the second nitride semiconductor layer 105, a gate recess 105a is formed. The depth of the gate recess 105a may be adjusted properly in a range where the gate recess 105a does not pass through the second nitride semiconductor layer 105.

Next, as shown in FIG. 8B, the p-type AlGaN layer 121 may be grown. Thereafter, a third nitride semiconductor layer, a gate electrode, a first ohmic electrode, and a second ohmic electrode may be formed in a similar manner to the process steps used in the case where the gate recess 105a is not formed. Also, the gate electrode and the third nitride semiconductor layer may be formed by the self-alignment process.

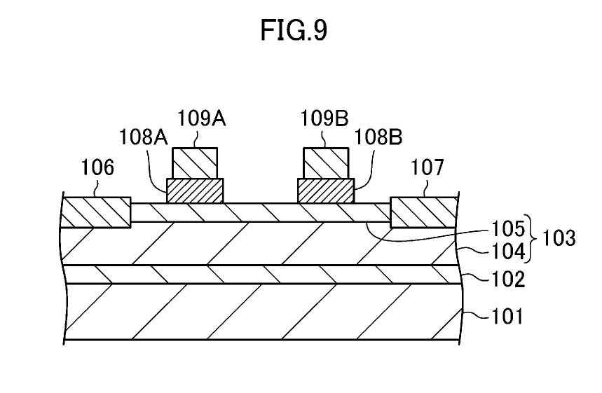

The nitride semiconductor device of this embodiment may be a double gate transistor. Specifically, as shown in FIG. 9, a first gate electrode 109A which forms a Schottky contact with a p-type third nitride semiconductor layer 108A is formed to be located between the first ohmic electrode 106 and the second ohmic electrode 107, and a second gate electrode 109B which forms a Schottky contact with a p-type fourth nitride semiconductor layer 108B is formed to be located between the first gate electrode 109A and the second ohmic electrode 107.

Also, when the nitride semiconductor device of this embodiment is a double gate transistor, the first gate electrode 109A, the second gate electrode 109B, the first ohmic electrode 106, and the second ohmic electrode 107 can be formed at the same time. The first gate electrode 109A and the third nitride semiconductor layer 108A, and the second gate electrode 109B and the p-type fourth nitride semiconductor layer 108B can be formed by self-alignment process. The nitride semiconductor device of this embodiment may be formed to have a configuration where the p-type third nitride semiconductor layer 108A and the p-type fourth nitride semiconductor layer 108B each have a gate recess structure.

According to the present disclosure, a nitride semiconductor device in which a gate leakage current generated when a forward bias is applied to a gate electrode is reduced can be realized. Therefore, the disclosed nitride semiconductor device and method for fabricating the same are useful as a nitride semiconductor device available for various applications such as a power transistor used for a power supply circuit, etc., and a method for fabricating the same.

What is claimed is:

1. A nitride semiconductor device, comprising:
a substrate;
a semiconductor layer stack including a first nitride semiconductor layer and a second nitride semiconductor layer stacked in this order on the substrate, the second nitride semiconductor layer having a wider bandgap than that of the first nitride semiconductor layer;
a p-type third nitride semiconductor layer selectively formed on the semiconductor layer stack;
a first gate electrode formed on the third nitride semiconductor layer; and
a first ohmic electrode and a second ohmic electrode formed on regions of the semiconductor layer stack located at both sides of the third nitride semiconductor layer, respectively,
wherein
the first gate electrode forms a Schottky contact with the third nitride semiconductor layer.

2. The nitride semiconductor device of claim 1, wherein
the first gate electrode, the first ohmic electrode, and the second ohmic electrode are made of the same material.

3. The nitride semiconductor device of claim 1, wherein
the first gate electrode, the first ohmic electrode, and the second ohmic electrode are each made of one of titanium, aluminum, tungsten, molybdenum, chromium, zirconium, indium, and tungsten silicide, or a stack including two or more of titanium, aluminum, tungsten, molybdenum, chromium, zirconium, indium, and tungsten silicide.

4. The nitride semiconductor device of claim 1, wherein
a width of the first gate electrode in a gate length direction and a width of the third nitride semiconductor layer in the gate length direction are equal to each other.

5. The nitride semiconductor device of claim 1, wherein
the first gate electrode and the third nitride semiconductor layer are etchable by the same etching gas.

6. The nitride semiconductor device of claim 1, wherein
a carrier concentration of the third nitride semiconductor layer is 1×10¹⁸ cm⁻³ or higher and 1×10²¹ cm⁻³ or lower.

7. The nitride semiconductor device of claim 1, wherein
the second nitride semiconductor layer has a gate recess, and
the third nitride semiconductor layer is formed to fill the gate recess.

8. The nitride semiconductor device of claim 1, further comprising:
a p-type fourth nitride semiconductor layer which is formed on the semiconductor layer stack to be located between the first gate electrode and the second ohmic electrode; and
a second gate electrode formed on the fourth nitride semiconductor layer,
wherein
the second gate electrode forms a Schottky contact with the fourth nitride semiconductor layer.

9. A method for fabricating a nitride semiconductor device, the method comprising the steps of:
(a) forming, on a substrate, a semiconductor layer stack including a first nitride semiconductor layer and a second nitride semiconductor layer stacked in this order, the second nitride semiconductor layer having a wider bandgap than that of the first nitride semiconductor layer;
(b) forming a p-type nitride semiconductor layer on the semiconductor layer stack, and then, selectively removing the p-type nitride semiconductor layer, thereby forming a third nitride semiconductor layer from the p-type nitride semiconductor layer; and
(c) forming a first ohmic electrode and a second ohmic electrode on regions of the semiconductor layer stack located at both sides of the third nitride semiconductor layer, respectively, and at the same time, forming a first gate electrode on the third nitride semiconductor layer.

10. The method of claim 9, wherein
in step (c), the first gate electrode, the first ohmic electrode, and the second ohmic electrode are formed by forming a resist mask to expose regions where the first gate electrode, the first ohmic electrode, and the second ohmic electrode are to be formed, and then, performing deposition and liftoff of an electrode formation film.

11. The method of claim 9, wherein
the electrode formation film is a film made of one of titanium, aluminum, tungsten, molybdenum, chromium, zirconium, indium, and tungsten silicide, or a stacked film including two or more of titanium, aluminum, tungsten, molybdenum, chromium, zirconium, indium, and tungsten silicide.

12. The method of claim 9, further comprising:
after the step (a) and before the step (b), the step (d) of forming a gate recess in the second nitride semiconductor layer,
wherein
in the step (b), the p-type nitride semiconductor layer is formed to fill the gate recess.

13. The method of claim 9, wherein
in the step (b), a p-type fourth nitride semiconductor layer is formed with a distance from the third nitride semiconductor layer, and
in the step (c), a second gate electrode is formed on the fourth nitride semiconductor layer.

14. The method of claim 9, wherein
a carrier concentration of the p-type nitride semiconductor layer is 1×10¹⁸ cm⁻³ or higher and 1×10²¹ cm⁻³ or lower.

15. A method for fabricating a nitride semiconductor device, the method comprising the steps of:
(a) forming, on a substrate, a semiconductor layer stack including a first nitride semiconductor layer and a second nitride semiconductor layer stacked in this order, the second nitride semiconductor layer having a wider bandgap than that of the first nitride semiconductor layer;
(b) forming a p-type nitride semiconductor layer and a gate electrode formation film in this order on the semiconductor layer stack on the substrate;
(c) selectively removing the gate electrode formation film and the p-type nitride semiconductor layer in this order to form a third nitride semiconductor layer and a first gate electrode on the semiconductor layer stack; and
(d) forming a first ohmic electrode and a second ohmic electrode on regions of the semiconductor layer stack located at both sides of the third nitride semiconductor layer, respectively.

16. The method of claim 15, wherein
the gate electrode formation film and the p-type nitride semiconductor layer are etchable by the same etching gas.

17. The method of claim 16, wherein
the gate electrode formation film is a film made of one of titanium, aluminum, tungsten, molybdenum, and tungsten silicide, or a stacked film including two or more of titanium, aluminum, tungsten, molybdenum, and tungsten silicide.

18. The method of claim 15, further comprising:
after the step (a) and before the step (b), the step (e) of forming a gate recess in the second nitride semiconductor layer,
wherein
in the step (b), the p-type nitride semiconductor layer is formed to fill the gate recess.

19. The method of claim 15, wherein
in the step (c), a p-type fourth nitride semiconductor layer and a second gate electrode are formed with a distance from the third nitride semiconductor layer and the first gate electrode.

20. The method of claim 15, wherein
a carrier concentration of the p-type nitride semiconductor layer is 1×10¹⁸ cm⁻³ or higher and 1×10²¹ cm⁻³ or lower.
